(19) United States
(12) Patent Application Publication
(10) Pub. No.: US 2005/0073050 A1
(43) Pub. Date: Apr. 7, 2005

(54) BGA package and printed circuit board for supporting the package

(75) Inventor: Chun Hung Chen, Shindian City (TW)

Correspondence Address: BACON & THOMAS, PLLC, 625 SLATERS LANE, FOURTH FLOOR, ALEXANDRIA, VA, 22314, US

(73) Assignee: VIA Technologies, Inc., Shindian City (TW)

(21) Appl. No.: 10/950,436

(22) Filed: Sep. 28, 2004

(30) Foreign Application Priority Data
Oct. 3, 2003 (TW) 092127527

(51) Int. Cl. H01L 23/52

(52) U.S. Cl. 257/738

(57) ABSTRACT

A ball-grid-array (BGA) package and a printed circuit board for supporting the package comprise a chip mounted on a first surface of a substrate, a plurality of power/ground solder balls disposed on a second surface of the substrate and next to the bottom of the chip, and a plurality of signal solder balls disposed on the second surface of the substrate and adjacent to the power/ground solder balls. Wherein, the power/ground solder balls are located between the chip and the signal solder balls.

### BACKGROUND OF THE INVENTION

1. Field of Invention

The invention relates to an arrangement of solder balls of a BGA package and, in particular, to an arrangement of power/ground solder balls and signal solder balls of a BGA package.

2. Related Art

To microminiaturize the chip size and to match the function demands, the optimized unit area accommodation on a microminiaturized chip is required. To operate correctly, the chip package is one of the main points that a design engineer should notice. After lots of designing and researching, the BGA package makes the chip function normally and provides a more miniature package structure than the conventional chips.

The BGA package is carried out by disposing ball shape metal solder balls on connecting pads of a circuit substrate with a layer of solder flux. After heating circuit substrate to a certain temperature, the melted metal solder balls connect the circuit substrate to another circuit board with wires, wherein other external wire-bonding processes are unnecessary. This packaging way makes packaging easier and also makes the multi-layer design possible to increase the design space for the other units.

Signal and power arrangement of conventional BGA package still has many shortages. In practice, units accommodating of the conventional BGA package is fixed. The power/ground solder balls and the signal solder balls are disposed adjacent to each other and placed at the periphery of the substrate, as a result the signals interfere reciprocally which lead to the problem of the chip operation. In addition, the signal lines of the signal solder balls must be disposed around the power/ground solder balls, so the signal lines of the signal solder balls should have larger turns. Alternatively, if the signal solder balls and the power/ground solder balls are too close, the signal solder balls must connect to the fourth layer of the substrate via through holes for signal lines connecting.

To avoid the malfunction of the chip due to the signal interference and raise the surface area of the external connecting power lines of the power area, the BGA package and a printed circuit board for supporting the package of the invention is provided to solve the problem of the conventional technology by redistributing the power area and the signal area.

### SUMMARY OF THE INVENTION

In view of the foregoing, the invention provides a signal arrangement structure of a BGA package, which has optimized arrangement of a power area and a signal area to avoid the signal interference of the chip caused by the power source or the high frequency, wherein the interference may lead to malfunction or mistakes. Furthermore, redistributing the power and the signal areas provides more effective surface for the power pads and it is easier to design.

The invention also provides a BGA package. A chip is mounted on the top surface of a substrate, and a packaging technology is used to connect the chip and the substrate. A plurality of power/ground solder balls and a plurality of signal solder balls are disposed on the bottom surface of the substrate. Wherein, the power/ground solder balls are located between the signal solder balls and the bottom of the chip, resulting in that the power transmission of the chip can directly connect to the power/ground solder balls without going around the signal solder balls. In addition, the signal solder balls can directly connected to the printed circuit board for carrying the BGA package, resulting in that the power surface between the chip and the substrate and that between the printed circuit board and the substrate are boarder to maintain the stability of the signal transmission among the chip, the substrate and the printed circuit board.

The invention also provides a printed circuit board, which has an area for carrying a BGA package. A plurality of power/ground pads and a plurality of signal pads are disposed on the area. The power/ground pads and the signal pads correspond to power/ground solder balls and signal solder balls of the BGA package, respectively. Wherein, the power/ground pads are between the signal pads and a chip of the BGA package. Therefore, the power/ground solder balls of the BGA package can directly connect to the power/ground pads of the printed circuit board, so that the power surface area of the package and the printed circuit board are increased.

In the invention, the power area of the BGA package is disposed around the chip and the signal area of the package is disposed in the periphery to avoid the reduction of the power surface due to the adjacency of the signal area and power area. After redistributing the power and signal areas, the effective surface of the power pads can be expanded.

### BRIEF DESCRIPTION OF THE DRAWINGS

The invention will become more fully understood from the detailed description given hereinbelow illustration only, and thus is not limitative of the present invention, and wherein:

FIG. 1A is a top view of solder balls arrangement of a BGA package substrate of the invention;

FIG. 1B is a sectional schematic illustration showing a solder ball arrangement of a BGA package substrate of this invention;

FIG. 2 is a sectional schematic illustration showing a printed circuit board of the invention; and

FIG. 3 is a top view of signal solder ball trace lines of the printed circuit board of the invention.

### DETAILED DESCRIPTION OF THE INVENTION

The present invention will be apparent from the following detailed description, which proceeds with reference to the accompanying drawings, wherein the same references relate to the same elements.

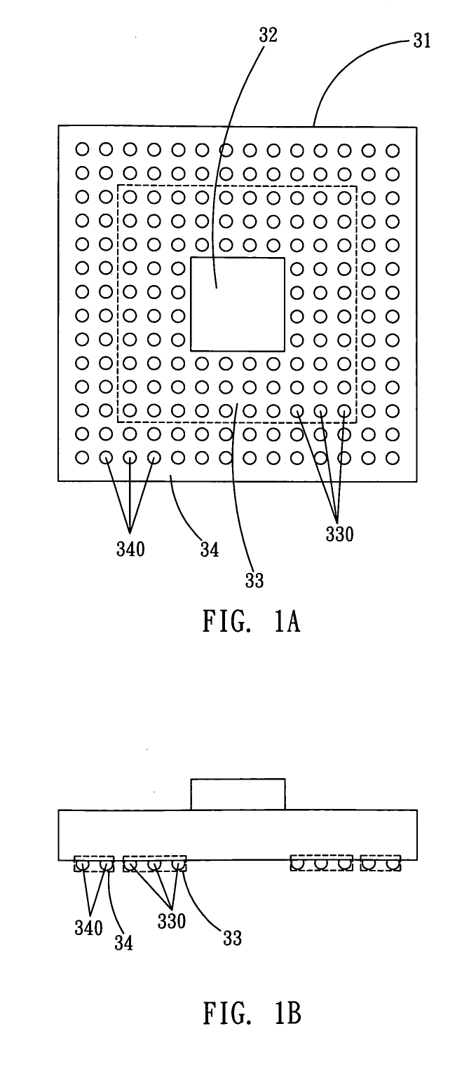

Referring to FIG. 1A, it shows a bottom view of a substrate 31. A chip 32 is disposed on the top surface of the substrate 31 and the position of the chip 32 is shown with the dot lines. The substrate 31 has a power/ground solder ball area 33 and a signal solder ball area 34, wherein the substrate 31 is a BGA package substrate. A plurality of power/ground solder balls 330 are placed in the power/ground solder ball area 33 to transmit power signals or ground signals of the chip 32. A plurality of signal solder balls 340 are placed in the signal solder ball area 34 to transmit the signals of the chip 32. The connections between the chip 32 to the power/ground solder balls 330 and the signal solder balls 340 are established by a way of wire bonding to connect the pads of the chip 32 and the top surface of the substrate 31. Since this is not the main part of the invention, it is omitted hereinafter.

Referring to FIG. 1A again, the power/ground solder ball area 33 is disposed next to the chip 32 and the signal solder ball area 34 is next to the power/ground solder ball area 33. That is, the power/ground solder ball area 33 is between the chip 32 and the signal solder ball area 34. Referring to FIG. 1B, the chip 32 is mounted on the top surface of the substrate 31, and the power/ground solder ball area 33 and the signal solder ball area 34 are disposed on the bottom surface of the substrate 31. The power/ground solder balls 330 are adjacent to the position of the chip 32 on the substrate 31, and the signal solder balls 340 are adjacent to the power/ground solder balls 330. This arrangement way of the solder balls makes the power signals or the ground signals of the chip 32 connect directly to the power/ground solder balls 330. Thus, the power surface or the ground surface between the chip 32 and the substrate 31 is boarder, so that the signal transmission between the chip 32 and the substrate 31 can be more stable.

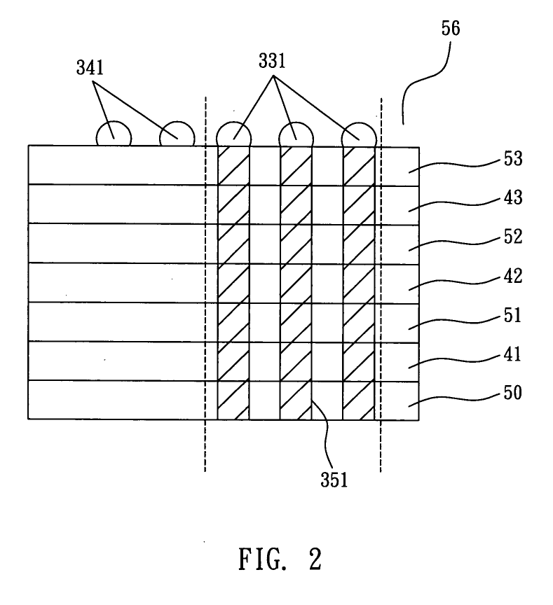

Referring to FIG. 2, it shows a printed circuit board 56 carrying the substrate 31 shown in FIG. 1A. To match the arrangement design of the substrate 31, the printed circuit board 56 carrying the substrate 31 must be designed corresponding to the power/ground area and the signal area.

Referring to FIG. 2, the printed circuit board 56 is composed of four circuitry layers, which are a first signal layer 50, a power signal layer 51, a ground signal layer 52 and a second signal layer 53 in sequence, wherein power/ground pads 331 and signal pads 341 are arranged on the second signal layer 53. An insulating layer 41 is disposed between the first signal layer 50 and the power signal layer 51, an insulating layer 42 is disposed between the power signal layer 51 and the ground signal layer 52, an insulating layer 43 is disposed between the ground signal layer 52 and the second signal layer 53, and the insulating layers 41, 42, 43 are used to isolate the signals of the four circuitry layers to avoid the short circuit of these four layers. When the substrate 31 is disposed on the circuit board 56 as shown in FIG. 1A, the substrate 31 is disposed on the right side of the power/ground pads 331 as shown in FIG. 2, and the power/ground pads 331 correspond to the power/ground solder balls 330 and the signal pads 341 corresponds to the signal solder balls 340. That is, the power/ground pads 331 are adjacent to the substrate 31 and the signal pads 341 are adjacent to the power/ground pads 331. In other words, power/ground pads 331 are between the signal pads 341 and the substrate 31. When this arrangement of pads is used in the circuit board 56, the power/ground pads 331 are connected to the other circuitry layers with the metal plugs 351, which pass through four circuitry layers of the printed circuit board. The design makes the power transmission between the substrate and the printed circuit board without passing via the signal solder balls of the substrate or the signal pads on the printed circuit board. Thus, the power surface or the ground surface between the substrate and the printed circuit board is boarder.

Referring to FIG. 1A and FIG. 2, the power/ground solder balls 330 and the signal solder balls 340 of the substrate 31 connect to the power/ground pads 331 and the signal pads 341 of the printed circuit board 56, respectively, to transmit the power signal, the ground signal and the general signals of the chip 32 on the substrate 31.

Referring to FIG. 2 again, the power/ground pads 331 disposed inside and the signal pads 341 disposed outside make the printed circuit board 56 connect to the signal pads 341 without passing via the power/ground pads 331. Passing through the outside and connect directly to the signal pads 341, the signal pads 341 connect to the other circuitry layers of the printed circuit board 56 without the metal plugs to increase the stability of the signals between the printed circuit board and the substrate.

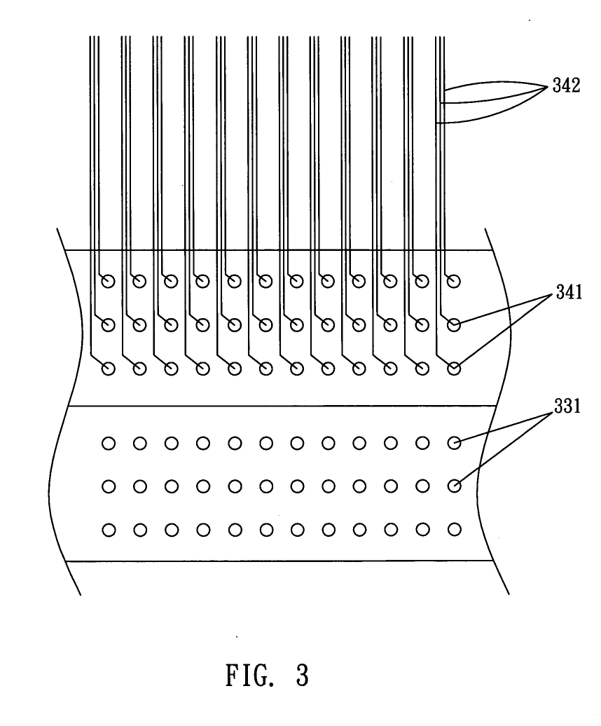

Referring to FIG. 3 showing a top view of the printed circuit board 56, the power/ground pads 331 and the signal pads 341 are arranged thereon. Power/ground pads 331 are arranged inside and the signal pads 341 are arranged outside. The printed circuit board connects to the signal pads 341 with the trace lines 342 and all the trace lines 342 submit without passing through the power/ground pads 331. That is, all the signal pads 341 can be connected with the trace lines 342. Thus, with the solder balls arrangement on the substrate in the invention, power/ground solder balls are disposed between the chip and the signal solder balls, which makes the signal pads and the power/ground pads of the printed circuit board carrying the substrate arrange in the similar way. The signal pads of the printed circuit board can connect directly to the first signal layer without using metal plugs or through holes, so there is enough space for the trace lines. Therefore, in the invention, the power/ground solder balls are disposed around the chip on the substrate and the signal solder balls are disposed outside the power/ground solder balls. Thus, the integrated circuit on the substrate of the package can possess a more stable signal.

The embodiment of the BGA package and a printed circuit board for supporting the package of the invention are described as above. From the description, the invention is known to be effective decrease the influence caused by the interference of the power signal, increase the power area surface which is occupied by the signal area on the conventional substrate and raise the space for more flexible and effective usage of the chip.

In summary, the BGA package and printed circuit board for supporting the package of the invention are more advanced in purpose and function, possess the industry utility and are new inventions never seen in the market. As this invention fits in with the patent system, this application is filed following the law.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

1. A ball-grid-array (BGA) package, comprising:
a chip, which is mounted on a first surface of a substrate;
a plurality of power/ground solder balls, which are disposed on a second surface of the substrate and are next to the bottom of the chip; and
a plurality of signal solder balls, which are disposed on the second surface of the substrate and are adjacent to the power/ground solder balls, wherein the power/ground solder balls are located between the chip and the signal solder balls.

2. The BGA package according to claim 1, wherein the power/ground solder balls are positioned in a first area, the signal solder balls are positioned in a second area, and the first area is between the second area and the bottom of the chip.

3. The BGA package according to claim 1, wherein the substrate is carried on a printed circuit board, a plurality of power/ground pads of the printed circuit board are connected to the power/ground solder balls, and a plurality of signal pads of the printed circuit board are connected to the signal solder balls.

4. The BGA package according to claim 3, wherein the power/ground pads are arranged between the signal pads and the chip.

5. The BGA package according to claim 3, wherein the printed circuit board is composed of four circuitry layers, which are a first signal layer, a power signal layer, a ground signal layer and a second signal layer in sequence, and the power/ground pads and the signal pads are arranged on the second signal layer.

6. The BGA package according to claim 5, wherein the signal pads are directly connected to trace lines of the second signal layer without passing via the first signal layer of the printed circuit board.

7. A printed circuit board, comprising:
a first signal layer;
a first insulating layer disposed on the first signal layer;
a power signal layer disposed on the first insulating layer;
a second insulating layer disposed on the power signal layer;
a ground signal layer disposed on the second insulating layer;
a third insulating layer disposed on the ground signal layer; and
a second signal layer disposed on the third insulating layer, wherein a BGA package is carried on the first signal layer, the first signal layer has a plurality of power/ground pads and a plurality of signal pads, and the power/ground pads are positioned between the signal pads and a chip of the BGA package.

8. The printed circuit board according to claim 7, wherein the power/ground pads are connected to a plurality of power/ground solder balls of the BGA package, and the signal pads are connected to a plurality of signal solder balls of the BGA package.

9. The printed circuit board according to claim 8, wherein the chip of the BGA package is mounted on a first surface of a substrate, the power/ground solder balls are disposed on a second surface of the substrate and the power/ground solder balls are located between the signal solder balls and the bottom of the chip.

10. The printed circuit board according to claim 7, wherein the signal pads are directly connected to trace lines of the printed circuit board to transmit signals.

11. The printed circuit board according to claim 7, wherein the power/ground pads are connected to the power layer, the ground layer and the first signal layer with a metal plugs or conductive holes.

12. The printed circuit board according to claim 7, wherein the power/ground pads are connected to a plurality of power/ground solder balls of the BGA package and the signal pads are connected to a plurality of signal solder balls of the BGA package.
